(19) United States
(12) Patent Application Publication
(10) Pub. No.: US 2003/0120756 A1
(43) Pub. Date: Jun. 26, 2003

(54) Mobile storage device for a network

(75) Inventor: Ming-Chih Chang, Taipei (TW)

Correspondence Address: Richard P. Berg, Esq., c/o LADAS & PARRY, Suite 2100, 5670 Wilshire Boulevard, Los Angeles, CA, 90036-5679, US

(73) Assignee: ICP Electronics Inc.

(21) Appl. No.: 10/109,930

(22) Filed: Mar. 29, 2002

(30) Foreign Application Priority Data
Dec. 24, 2001 (TW) 90132079

(51) Int. Cl. G11C 5/00

(52) U.S. Cl. 709/220

(57) ABSTRACT

A mobile storage device for a network. The device integrates with the network interface technique to share and monitor network resources concurrently without the use of installing additional drivers. The device includes: a storage unit, to store data; a network interface, to provide communication control between the storage unit and other external devices; a transmission medium, to connect the network interface to an external computer having a network browser to receive an input data access request from the network browser and display the data stored in the storage unit on the network browser in response to the data access request. The device further includes an operating system to send a data access control signal and a processor to perform the data access control. Standard network interface and protocols such as Ethernet and TCP/IP, can be used for the network interface.

### BACKGROUND OF THE INVENTION

1. Field of the Invention

This invention relates to a network storage device, particularly to a mobile storage device for a network, which integrates with the network interface technique to share and monitor network resources concurrently without the use of installing additional drivers.

2. Description of the Prior Art

For computers, data storage ability is very important. As shown in FIG. 1, in addition to the compact data storage requirement for a computer 10, the data stored in the computer 10 is also required to be stable, portable and flexible. As such, the development of data processing techniques, including data backup ability has become important. However, current built-in storage device 11 lacks portability. Further, the Windows operating system 18 in the computer 10 connecting to external storage device 14 and remote storage device 15 respectively using, for example, USB device 12 and IEEE 1394 device 13, lacks flexibility in providing different data to different devices. Furthermore, peripheral device such as a printer 17, must install the relative driver such as the printer interface 16 to activate the device. These make data backup and access inconvenient. Such examples mentioned above include: LaCie's 10 Gb pocketed drive, which can support USB and IEEE 1394 devices but has the poor operating rate on the USB device; Flotech's pocketed product, which only support the USB device; Toshiba's 2 Gb Type II Card hard drive, which can not be used in a desktop computer; and Zip drive, which will vibrate in use and appear the reliability problem.

### SUMMARY OF THE INVENTION

Accordingly, the primary object of this invention is to provide a mobile storage device for a network, which integrates with the network interface technique to share and monitor network resources concurrently without installing additional drivers.

To realize the above and other objects, this invention provides a mobile storage device for a network that includes: a storage unit, to store data; a network interface, to provide communication control between the storage unit and other external devices; a transmission medium, to connect the network interface to an external computer having a network browser, so as to receive a data access request from the network browser and display the data stored in the storage unit on the network browser in response to the data access request. The invention further includes an operating system to send a data access control signal and a processor to perform data access control. The network interface can use a standard network interface and protocol such as Ethernet and TCP/IP.

Therefore, the invention can share data with multiple devices without additional drivers due to the standard network interface, and its storage ability designed to flexibly meet the need for compact storage. In addition, the storage unit can use a RAID configuration to safely and reliably protect stored data.

### BRIEF DESCRIPTION OF THE DRAWINGS

FIG. 1 is a schematic diagram illustrating a typical storage device and computer configuration;

FIG. 2 is a schematic diagram illustrating the mobile storage device of the invention; and

FIG. 3 is a flowchart of the operation of the mobile storage device according to the invention.

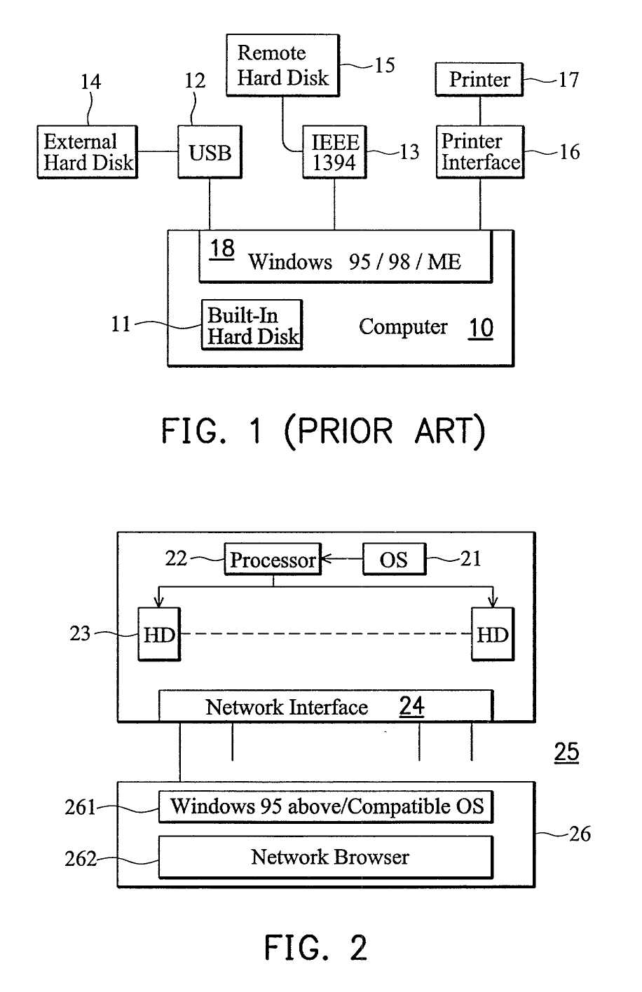

### DETAILED DESCRIPTION OF THE INVENTION

FIG. 2 is a schematic diagram illustrating the mobile storage device for a network according to the invention. The mobile storage device for a network includes: an operating system 21; a processor 22, storage units 23; a network interface 24; and multiple transmission media 25.

As shown in FIG. 2, an external computer 26 having a Windows 95 and above or compatible operating system 261 and a network browser 262 accesses the data stored in the storage units 23 through a transmission media connection. Also, multiple local and remote computers or data processing devices, such as a desktop computer or notebook (not shown), can concurrently be connected to the mobile storage device through the multiple transmission media 25 to obtain the multi-task function. When a user sends a data access request through the network browser 262 of the computer 26, the operating system 261 of the external computer 26 transfers the data access request through the connected transmission media 25 and the network interface 24 into the inventive device. The operating system 21 of the inventive device sends a data access control signal to the processor 22 in response to the data access request. The processor 22 accesses the data in the storage units 23 according to the data access control signal, for example, to access the data in the first and last storage units 23. When the data access requests come from different computers, the inventive device uses a time-sharing technique. For example, corresponding to the externally relative computers, the inventive device stores data in the first storage unit and output data from the last storage unit, respectively. The result transfers back to be displayed on the browser 262 of the external computer 26 by the operating system 21 through the network interface 24 and the transmission media 25. The network interface 24 can use a standard network interface and protocol such as Ethernet and TCP/IP. The operating systems 21, 261 can use a Windows 95 and above or compatible operating system, to have the feature of omitting the prior driver.

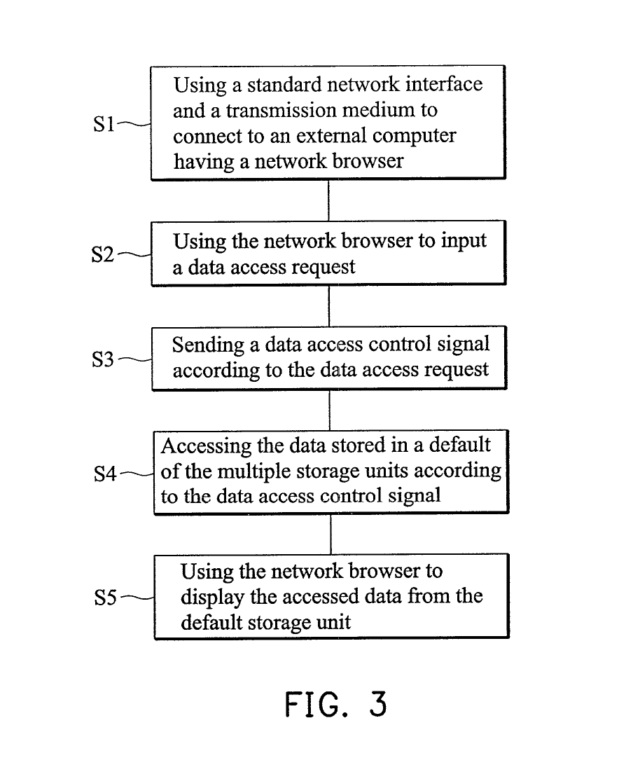

Accordingly, as shown in FIG. 3, an operating method applied to the inventive device of FIG. 2 includes: using a standard network interface and a transmission medium to connect to an external computer having a network browser (S1); using the network browser to input a data access request (S2); sending a data access control signal in response to the data access request (S3); accessing the data stored in a default of the storage units according to the data access control signal (S4); and using the network browser to display the accessed data from the default storage unit (S5).

To summarize, this invention provides data sharing across multiple devices without additional drivers due to the standard network interface, and its storage ability designed to flexibly meet the need for compact storage. In addition, the storage units can use 2.5″ drives with a network drive configuration, such as RAID, to set the drive name used by the operating system for providing the best resource utility. Further, the flexibility given by the network drive configuration can safely and reliably protect stored data and provide higher data operating rate than the prior art, for example up to 100 Mbps.

Although the present invention has been described in its preferred embodiment, it is not intended to limit the invention to the precise embodiment disclosed herein. Those who are skilled in this technology can still make various alterations and modifications without departing from the scope and spirit of this invention. Therefore, the scope of the present invention shall be defined and protected by the following claims and their equivalents.

What is claimed is:

1. A mobile storage device for a network, comprising:
a storage unit, to store data;
a network interface, to provide communication control between the storage unit and other external devices;
a transmission medium, to connect the network interface to an external computer having a network browser, so as to receive a data access request from the network browser and display the data stored in the storage unit on the network browser in response to the data access request.

2. The mobile storage device for a network of claim 1, further comprising an operating system to output a data access control signal according to the data access request and a processor to execute the data access control according to the data access control signal.

3. The mobile storage device for a network of claim 1, wherein the network interface is an Ethernet interface.

4. The mobile storage device for a network of claim 1, wherein the network interface is TCP/IP-enabled.

5. The mobile storage device for a network of claim 1, wherein the storage unit is a 2.5″ hard disk using the network drive configuration.
